(19) United States
(12) Patent Application Publication
(10) Pub. No.: US 2022/0406776 A1
(43) Pub. Date: Dec. 22, 2022

(54) STACKED FET WITH DIFFERENT CHANNEL MATERIALS

(71) Applicant: INTERNATIONAL BUSINESS MACHINES CORPORATION, ARMONK, NY (US)

(72) Inventors: Ruilong Xie, Niskayuna, NY (US); Eric Miller, Watervliet, NY (US); Dechao Guo, Niskayuna, NY (US); Jeffrey C. Shearer, Albany, NY (US); Su Chen Fan, Cohoes, NY (US); Julien Frougier, Albany, NY (US); Veeraraghavan S. Basker, Schenectady, NY (US); Junli Wang, Slingerlands, NY (US); Sung Dae Suk, Watervliet, NY (US)

(21) Appl. No.: 17/304,392

(22) Filed: Jun. 21, 2021

(51) Int. Cl. H01L 27/092; H01L 29/04; H01L 29/06; H01L 29/423; H01L 29/786; H01L 21/02; H01L 21/8238; H01L 29/66

(52) U.S. Cl. CPC H01L 27/0922; H01L 29/045; H01L 29/0665; H01L 29/42392; H01L 29/78651; H01L 29/78684; H01L 29/78696; H01L 21/0259; H01L 21/02532; H01L 21/02609; H01L 21/823807; H01L 29/66742

(57) ABSTRACT

A semiconductor device comprising at least one first gate all around channel having a horizontal physical orientation, wherein the at least one first gate all around channel is comprised of a first material, wherein the at least one first gate all around channel has a sidewall surface with (100) crystal orientation. At least one second gate all around channel having a vertical physical orientation, wherein the second channel is located above the at least one first gate all around channel, wherein the at least one second gate all around channel is comprised of a second material, wherein the at least one second gate all around channel has a sidewall surface with (110) crystal orientation. A gate metal enclosing the at least one first gate all around channel and the at least one second gate all around channel.

### BACKGROUND

The present invention relates generally to the field of stacked transistors, and more particularly to concurrently forming the transistors with different channel materials in specific channel orientation to increase channel mobility in the structure.

Stacked transistor is an attractive device architecture for advanced CMOS node. By stacking one device over the other, it allows further area scaling beside conventional gate pitch and BEOL metal pitch scaling. Conventional stacked transistor has both top and bottom devices where the stacked transistors use the same channel materials and have the same channel orientations, which are not optimized for channel mobilities.

### BRIEF SUMMARY

Additional aspects and/or advantages will be set forth in part in the description which follows and, in part, will be apparent from the description, or may be learned by practice of the invention.

A semiconductor device comprising at least one first gate all around channel having a horizontal physical orientation, wherein the at least one first gate all around channel is comprised of a first material, wherein the at least one first gate all around channel has a sidewall surface with (100) crystal orientation. At least one second gate all around channel having a vertical physical orientation, wherein the second channel is located above the at least one first gate all around channel, wherein the at least one second gate all around channel is comprised of a second material, wherein the at least one second gate all around channel has a sidewall surface with (110) crystal orientation. A gate metal enclosing the at least one first gate all around channel and the at least one second gate all around channel.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1A illustrates a top-down view of a stacked FET device, in accordance with an embodiment of the present invention.

FIG. 1B illustrates a cross-section A of the top-down view of the stacked FET device, in accordance with the embodiment of the present invention.

FIG. 2A illustrates a top-down view of the stacked FET device, in accordance with an embodiment of the present invention.

FIG. 2B illustrates cross-section A of the top-down view of the stacked FET device, in accordance with the embodiment of the present invention.

FIG. 3A illustrates a top-down view of the stacked FET device, in accordance with an embodiment of the present invention.

FIG. 3B illustrates cross-section A of the top-down view of the stacked FET device, in accordance with the embodiment of the present invention.

FIG. 4A illustrates a top-down view of the stacked FET device, in accordance with an embodiment of the present invention.

FIG. 4B illustrates cross-section A of the top-down view of the stacked FET device, in accordance with the embodiment of the present invention.

FIG. 4C illustrates cross-section B of the top-down view of the stacked FET device, in accordance with the embodiment of the present invention.

FIG. 5A illustrates a top-down view of the stacked FET device, in accordance with an embodiment of the present invention.

FIG. 5B illustrates cross-section A of the top-down view of the stacked FET device, in accordance with the embodiment of the present invention.

FIG. 5C illustrates a cross-section B of the top-down view of the stacked FET device, in accordance with the embodiment of the present invention.

FIG. 6 illustrates a cross-section of the process stage of the formation of the device, in accordance with the embodiment of the present invention.

FIG. 7 illustrates a cross-section of the process stage of the formation of the device, in accordance with the embodiment of the present invention.

FIG. 8 illustrates a cross-section of the process stage of the formation of the device, in accordance with the embodiment of the present invention.

FIG. 9 illustrates a cross-section of the process stage of the formation of the device, in accordance with the embodiment of the present invention.

FIG. 10 illustrates a cross-section of the process stage of the formation of the device, in accordance with the embodiment of the present invention.

FIG. 11 illustrates a cross-section of the process stage of the formation of the device, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various process used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (ME), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, wherein like reference numerals refer to like elements throughout. Stacked FET devices can include stacked nanosheet transistors comprised of Si channel or SiGe channel. Typically, both Si and the SiGe channel transistors have a horizontal orientation (i.e., longer width wise than vertical height).

When forming the SiGe channel having a specific orientation (horizontal or vertical), the thickness of the channel to be form affects the rate of defects formed in the channel. For example, the rate of defects increases as the channel thickness increases. A vertical orientated channel tends to be thicker (i.e. vertical height) than a horizontal orientated channel. More fabrication time is needed to form the thicker channel, thus providing more opportunities for defects to be introduced into the channel. Defects can be introduced into a horizontal channel comprised of SiGe. The defects can be caused by forming the channel, by the percentage of Ge within the channel, or other factors leading to defects. The defects rate within the channel increases as the percentage of Ge increases, thus having a high percentage of Ge tends to lead to more defects forming in the channel. The defect formation rate within the channel can be controlled or limited by controlling the percentage of Ge within the channel. Since the defect rate can be managed by controlling the Ge percentage, then a SiGe channel having a vertical orientation can be formed.

When forming channels comprised of Si, a sacrificial layer is used to separate the individual layers of Si. The material for the sacrificial layer is usually a doped Si, for example, SiGe. Once the Ge % in the sacrificial material reaches a high percentage (55%+) then defects start to form in the sacrificial layer. Therefore, the percentage of Ge in the sacrificial layer is under 55%. During fabrication the sacrificial layer is removed, but difficulty arises when the sacrificial layer is comprised of SiGe and one of the channels is composed of SiGe. Being able to selectively remove one-layer SiGe and not damage another layer of SiGe is difficult. The selective targeting of layers can be achieved by controlling the Ge percentages in the layers. The sacrificial layer can be targeted for selective removal by having a higher percentage of Ge in the sacrificial layer than the percentage of Ge in the channel layer. Vertical channels or horizontal channels comprised of SiGe where the percentage of Ge in the range of about 5 to 35%. The sacrificial layer comprised of SiGe where the percentage of Ge in the sacrificial layer to be about 50%. The percentage difference of Ge in sacrificial layer and the channel allows for the selective removal of the sacrificial layer while leaving the channel layer alone. Thus, the sacrificial layer can be selectively etched while the channel layer remains.

The mobility of the transistors can be increased by changing the physical orientation of at least one of the transistors (i.e., horizontal to vertical). Furthermore, the mobility of the transistors can be optimized by controlling the channel orientations of the transistors. When the lower NFET transistor has a channel sidewall surfaces with (100) crystal orientations and the upper PFET transistor has a channel sidewall surfaces with (110) crystal orientations, the crystalline orientation (structure) of the transistors allows for an optimized electron and hole mobilities of the NFET and PFET, respectively. The top transistor has a vertical orientation with a channel sidewall surface having (110) crystal orientation, while the lower transistors can have a vertical orientation or a horizontal orientation with a channel sidewall surface having (100) crystal orientation.

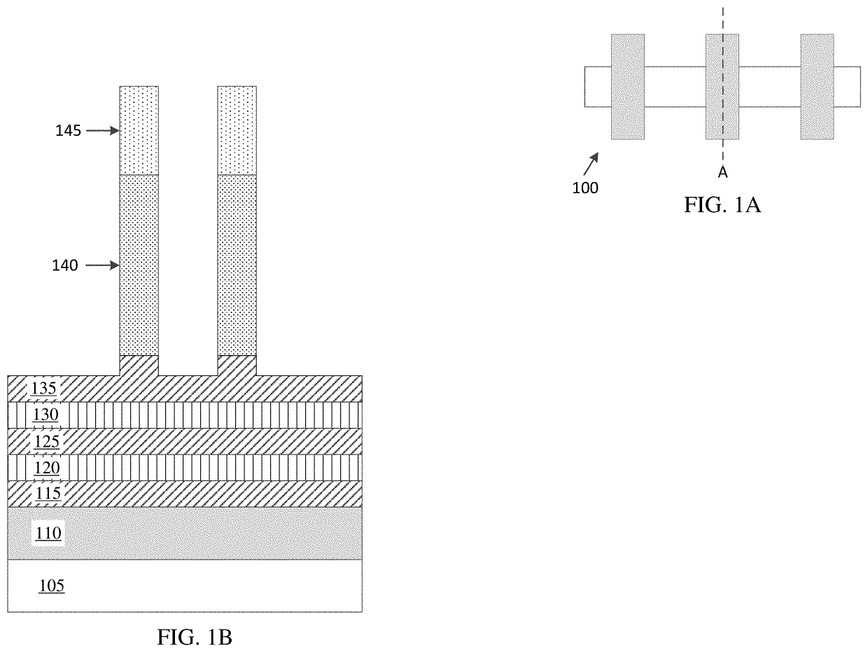

FIG. 1A illustrates a top-down view of a stacked FET device 100, in accordance with an embodiment of the present invention. FIG. 1B illustrates a cross-section A of the top-down view of the stacked FET device 100, in accordance with the embodiment of the present invention. FIG. 1B illustrates the stacked FET device 100 after the initial fabrication stages. The stacked FET device 100 includes a substrate 105, an oxide layer 110, a first layer 115, a second layer 120, a third layer 125, a fourth layer 130, a fifth layer 135, a sixth layer 140, and a hard mask 145. The first layer 115, the third layer 125, and the fifth layer 135 are sacrificial layers that located above and below the layers that will be the transistors (i.e., the second layer 120 and the fourth layer 130). The number of layers illustrated by figures are for exemplary purposes only. There can be fewer layers or more layers, as long as, a sacrificial layer are used to separate the transistor layers. The substrate 105 can be comprised of a silicon wafer, a sapphire wafer, or any type of suitable layer that allows for the formation of the nanosheet device 100. The oxide layer 110 is formed on top of the substrate 105. The first layer 115 is formed on top of the oxide layer 110. The first layer 115 can be comprised of, for example, SiGe 50%. A second layer 120 is formed on top of the first layer 115. The second layer 120 has a horizontal orientation, i.e., the second layer 120 is wider than it is taller. The third layer 125 is formed on top of the second layer 120. The third layer can be comprised of, for example, SiGe 50%. A fourth layer 130 is formed on top of the third layer 125. The fourth layer 130 has a horizontal orientation, i.e., the fourth layer 130 is wider than it is taller. The fifth layer 135 is formed on top of the fourth layer 130. The fifth layer 135 can be comprised of, for example, SiGe 50%. The concentration of Ge in the first layer 115, the third layer 125 and the fifth layer 135 is not limited to 50%. The concentration of Ge in the layers needs to be a high enough percentage to differentiate between the sacrificial layers (i.e., the first layer 115, the third layer 125, and the fifth layer 135), and other layers of SiGe that have a lower percentage of Ge. The sixth layer 140 is formed on top of the fifth layer 135. FIG. 1B illustrates the sixth layer 140 has been processed to form a plurality of vertical fins on top of the fifth layer 135. The second layer 120 and the fourth layer 130 is comprised of a first material and the sixth layer 140 is comprised of a second material. Different materials are used in the first material and the second material. The first material can be selected from a group consisting of Si or SiGe 5-35%. The second material can be selected from a group consisting of Si or SiGe 5-35%. For example, the first material comprising the second layer 120 and the fourth layer 130 can be Si having a channel sidewall surfaces with (100) crystal orientations and the second material comprising the sixth layer 140 can be SiGe 5-35% having a channel sidewall surfaces with (110) crystal orientations. Alternatively, first material comprising the second layer 120 and the fourth layer 130 can be SiGe 5-35% having a channel sidewall surfaces with (100) crystal orientations and the second material comprising the sixth layer 140 can be Si having a channel sidewall surfaces with (110) crystal orientations. The hard mask 145 is formed on top of the sixth layer 140.

FIG. 1B illustrates the initial formation of a stacked FET stack that is comprised of alternating layers to form the horizontal transistors. FIG. 1B illustrates that the bottom horizontal transistor contains two horizontal nanosheet channels (i.e., the second layer 120, and the fourth layer 130), but this is meant for exemplary purposes only. The stacked FET stack can be comprised of fewer or more alternating layer to increase or decrease the number of nanosheet channels that will be formed. FIG. 1B also illustrates the formation of the top horizontal transistor which is comprised of two vertical channels (i.e., the sixth layer 140), but it can have fewer or more vertical channels.

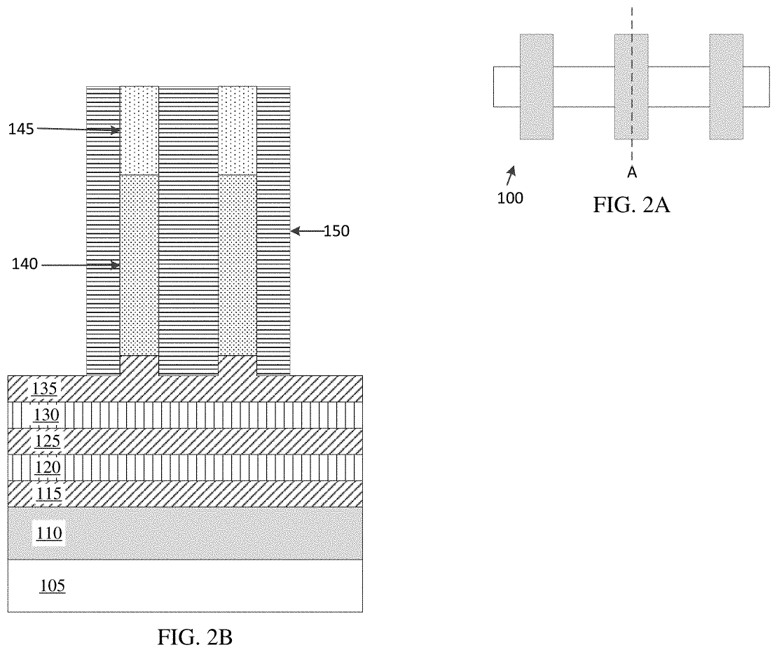

FIG. 2A illustrates a top-down view of the stacked FET device 100, in accordance with an embodiment of the present invention. FIG. 2B illustrates cross-section A of the top-down view of the stacked FET device 100, in accordance with the embodiment of the present invention. A spacer 150 is formed on the exposed surfaces of fifth layer 135, the sixth layer 140 and the hard mask 145. The spacer 150 is etched, for example, by reactive ion etching (RIE) to remove most of the spacer 150 material located on top of the fifth layer 135. The spacer 150 that remains is located on the sides of the columns of the sixth layer 140 and the hard mask 145.

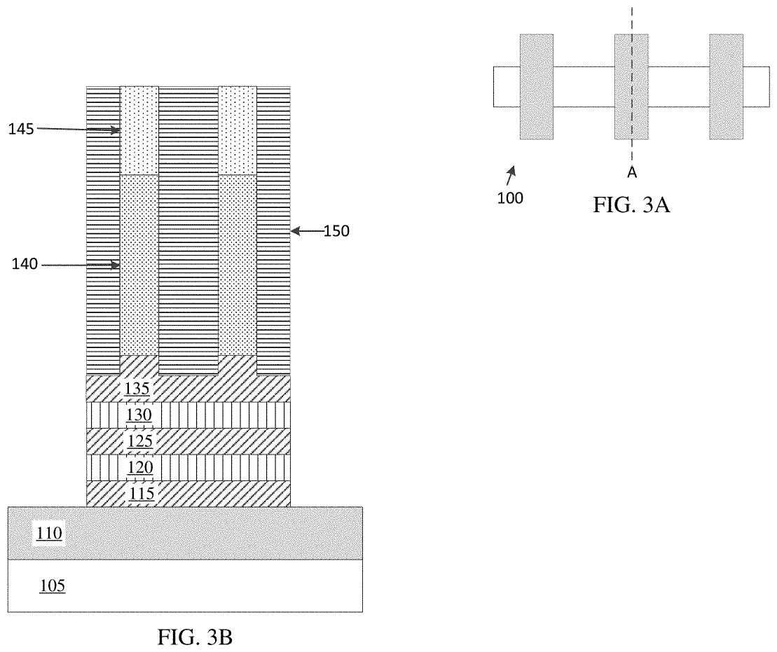

FIG. 3A illustrates a top-down view of the stacked FET device 100, in accordance with an embodiment of the present invention. FIG. 3B illustrates cross-section A of the top-down view of the stacked FET device 100, in accordance with the embodiment of the present invention. The horizontal layers of the nanosheet stack are etched to reduce the width of the first layer 115, the second layer 120, the third layer 125, the fourth layer 130, and the fifth layer 135. The width of the horizontal layers is reduced to be substantially equal to the total width of the vertical columns. Where the total width of the vertical columns is comprised of the combined width of the spacer 150, the sixth layer 140 and the hard mask 145. FIGS. 3B and 3C illustrate one way how a bottom nanosheet width is defined. Alternatively, a lithography and etching process can be applied to pattern the bottom nanosheet stack to a different width compared to the total width of vertical columns of top transistor.

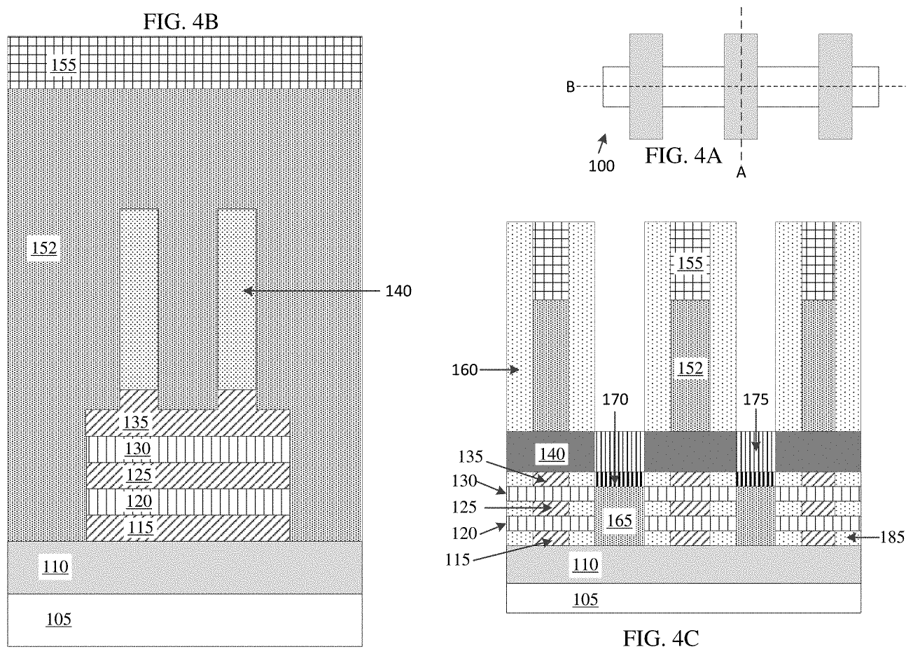

FIG. 4A illustrates a top-down view of the stacked FET device 100, in accordance with an embodiment of the present invention. FIG. 4B illustrates cross-section A of the top-down view of the stacked FET device 100, in accordance with the embodiment of the present invention. The spacer 150 and hard mask 145 are removed and a dummy gate 152 is formed on top of the exposed surfaces of the oxide layer 110, the nanosheet stack, and the columns. The dummy gate 152 encloses the exposed areas of the horizontal sections of the nanosheet stack and the exposed areas of the vertical sections of the columns. A hard mask 155 is formed on top of the dummy gate 152.

FIG. 4C illustrates cross-section B of the top-down view of the stacked FET device 100, in accordance with the embodiment of the present invention. After dummy gate 152 patterning, a gate spacer 160 is formed at sidewall of the dummy gate 152 and hard mask 155. After that, a selective SiGe50 indentation process is used to form cavities over the sacrificial layers (i.e., the first layer 115, the third layer 125, and the fifth layer 135). Please note that by having top channel material 140 with SiGex where Ge % is less than 35%, it is able to create such cavities inside SiGe50 without damaging the top channel material (i.e., the sixth layer 140). After that, an inner spacer 185 is formed on the sides of the first layer 115, the third layer 125, and the fifth layer 135 to fill the said cavities. After that, bottom source/drain epi 165, isolation layer 170, and top source/drain epi 175 are formed. The bottom source/drain epi layer 165 can be selected from a group consisting of a N-epi or a P-epi material. The top source/drain epi layer 175 can be selected from a group consisting of either a N-epi or a P-epi.

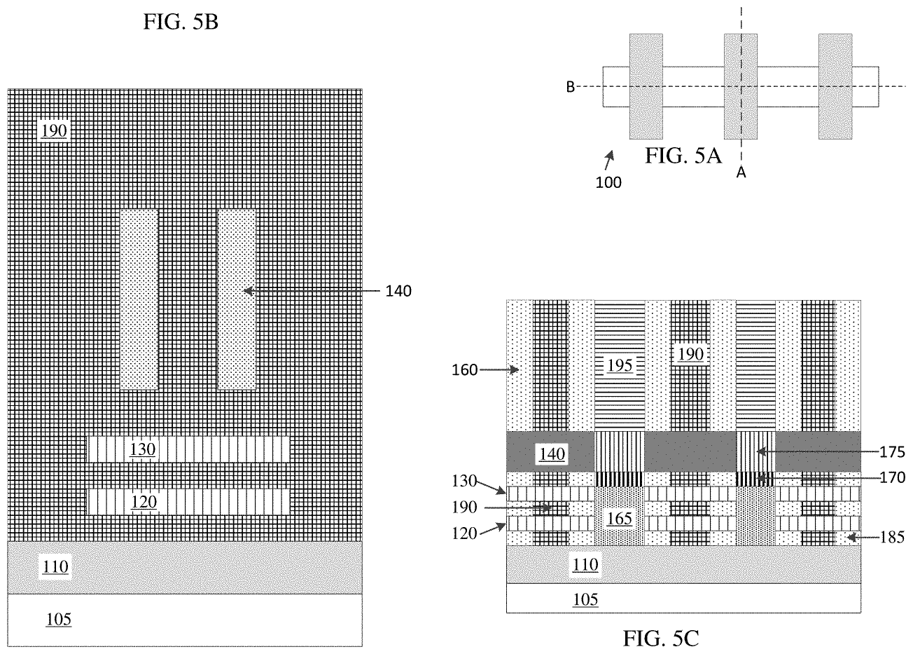

FIG. 5A illustrates a top-down view of the stacked FET device 100, in accordance with an embodiment of the present invention. FIG. 5B illustrates cross-section A of the top-down view of the stacked FET device 100, in accordance with the embodiment of the present invention. The dummy gate 152, and the hard masks 155 are removed, followed by removal of sacrificial layers (i.e., the first layer 115, the third layer 125, and the fifth layer 135). By having high Ge % in sacrificial layers when compared to top channel (i.e., the sixth layer 140), it is able to selectively remove sacrificial materials without damaging the top channels with suitable chemistry, such as vapor phased HCl. After that, replacement gate 190 that can be comprised of a material selected from a group consisting of a high-k gate dielectric, work function metals, and conductive gate metal fill material are formed. The high-k metal gate 190 encloses the second layer 120, the fourth layer 130, and the sixth layer 140. FIG. 5C illustrates cross-section B of the top-down view of the stacked FET device 100, in accordance with the embodiment of the present invention. The stacked FET device 100 undergoes a substitution process where the layers with the high Ge %, i.e., the first layer 115, the third layer 125, and the fifth layer 135 are replaced with a replacement gate 190. The replacement gate 190 further fills the space located between the spacers 160, since the dummy gate 152 was removed. A second ILD 195 is formed on the top of the second epi layer 175 between each of the columns. At this stage, the top PFET is with SiGe channel material and (110) surface orientation, which is favor for boosting hole mobility. The bottom NFET device is with Si channel and (100) surface orientation, which is good for electron mobility.

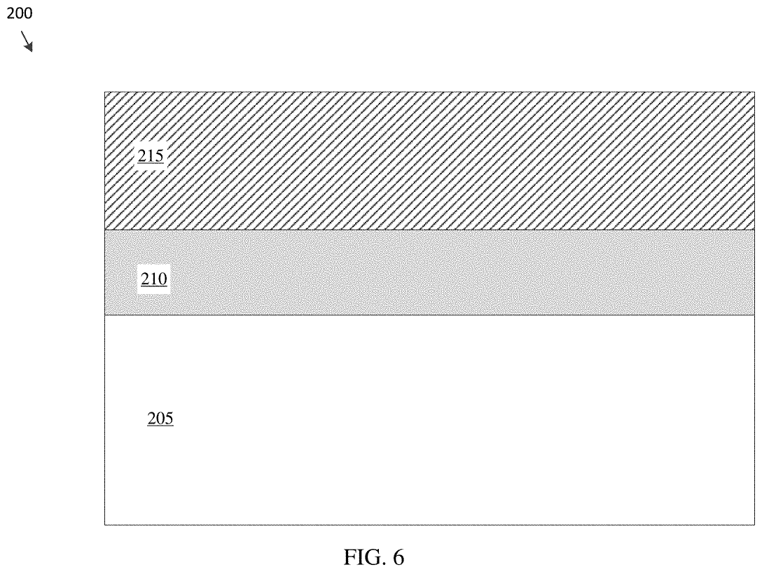

FIG. 6 illustrates a cross-section of the process stage of the formation of the device 200, in accordance with the embodiment of the present invention. The device 200 includes a bonded channel 210 over the substrate 205. When wafer bonding is performed, it is purposely rotate the donor or accepter wafer by 45 degree. Bounding channel 210 can be comprised of a bonding dielectric, such as oxide. The substrate 205 and the upper layer 215 are comprised of different materials. The substrate 205 material could be Si, and upper layer 215 material could be SiGe5-50%, alternatively, the substrate 205 material could be SiGe5-50%, and upper layer 215 material could be Si.

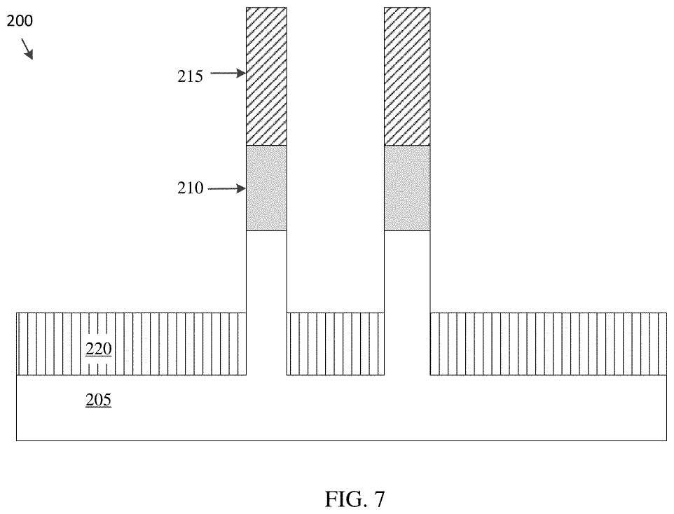

FIG. 7 illustrates a cross-section of the process stage of the formation of the device 200, in accordance with the embodiment of the present invention. The device 200 is etched to form at least one FIN comprised of the substrate 205, the wafer bonding layer 210, and the upper layer 215. FIG. 7 illustrates the formation of two FINs, however, device 200 can have fewer or more FINs than what is illustrated by FIG. 7. A shallow trench isolation layer 220 is formed on top of the substrate 205. Because 45-degree rotation is done before wafer bonding, the top (upper layer 215) and bottom channel (substrate 205) can have different crystal orientations at channel sidewall surfaces. In the case top channel material 215 is SiGe, the sidewall surface is with (110) crystal orientation, and for the bottom Si channel 205, the sidewall surface is with (100) crystal orientation.

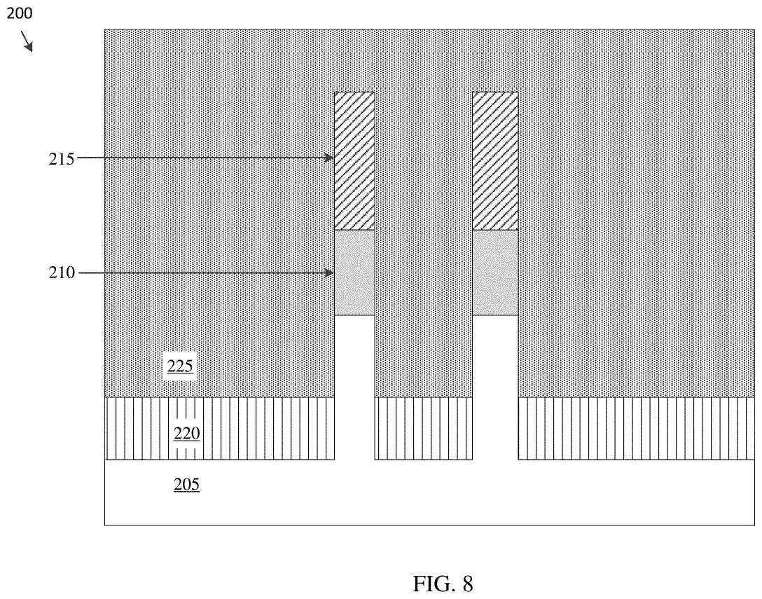

FIG. 8 illustrates a cross-section of the process stage of the formation of the device 200, in accordance with the embodiment of the present invention. At a downstream stage of the device 200 fabrication, a high-k metal gate 225 is formed on top of the shallow trench isolation layer 220. The high-k metal gate 225 encloses the FINs, such that, the high-k metal gate 225 is in direct contact with the sides the substrate 205, the wafer bonding layer 210, and the upper layer 215 that comprises each column. At this stage, the top PFET is with SiGe channel material and (110) surface orientation, which is favor for boosting hole mobility. The bottom NFET device is with Si channel and (100) surface orientation, which is good for electron mobility.

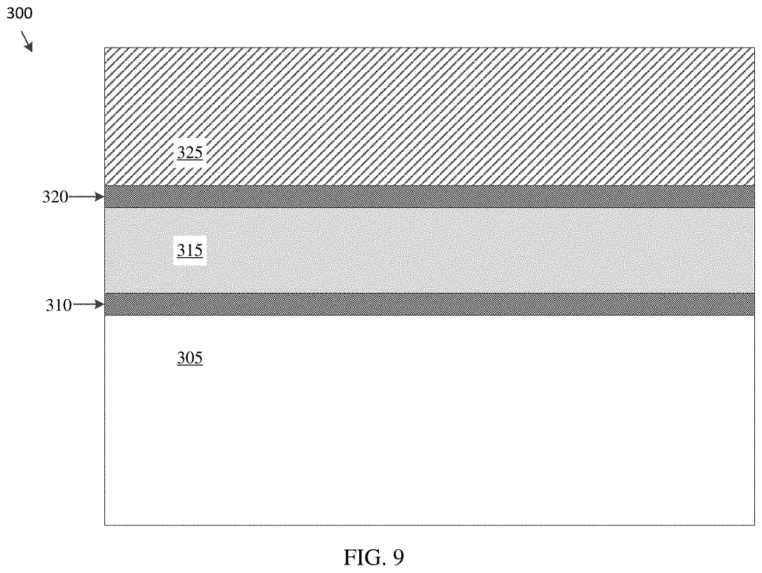

FIG. 9 illustrates a cross-section of the process stage of the formation of the device 300, in accordance with the embodiment of the present invention. The device includes a bonded channel 315 over the substrate 305. Before wafer bonding, epitaxy sacrificial layers (first sacrificial layer 310 and the second sacrificial layer 320) are comprised of high Ge % SiGe (>50% Ge %) that is grown over the substrate 305 and the bonded channel 315. When wafer bonding is performed, it is purposely rotate the donor or accepter wafer by 45 degree. The bonding channel 315 can be comprised of a bonding dielectric, such as oxide. An upper layer 325 is formed on top of the second sacrificial layer 320. The substrate 305 and the upper layer 325 are comprised of different materials. The substrate 305 can be comprised of Si, and upper layer can be comprised of SiGe5-35%, alternatively, the substrate 305 material could be SiGe5-35%, and upper layer 325 material could be Si.

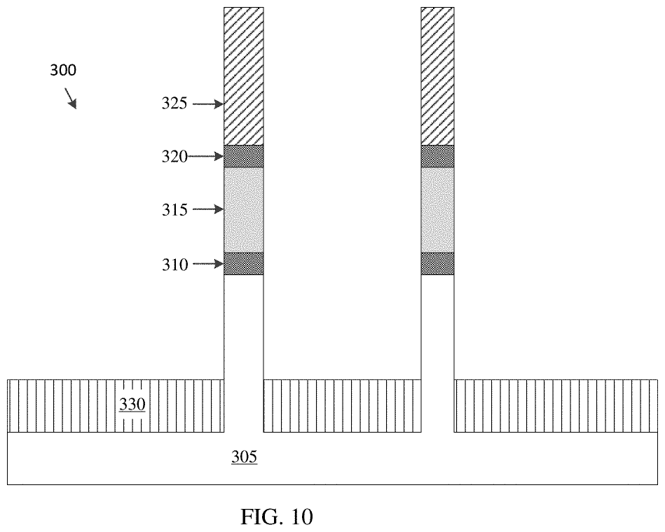

FIG. 10 illustrates a cross-section of the process stage of the formation of the device 300, in accordance with the embodiment of the present invention. The device 300 is etched to form at least one Fin comprised of the substrate 305, the first sacrificial layer 310, the wafer bonding layer 315, the second sacrificial layer 320, and the upper layer 325. FIG. 10 illustrates the formation of two Fins, however, device 300 can have fewer or more columns than what is illustrated by FIG. 10. A shallow trench isolation layer 330 is formed on top of the substrate 305. Because 45-degree rotation is done before wafer bonding, the top and bottom channel could have different crystal orientations at channel sidewall surfaces. In the case top channel material (upper layer 325) is SiGe, the sidewall surface is with (110) crystal orientation, and for the bottom Si channel (substrate 305), the sidewall surface is with (100) crystal orientation.

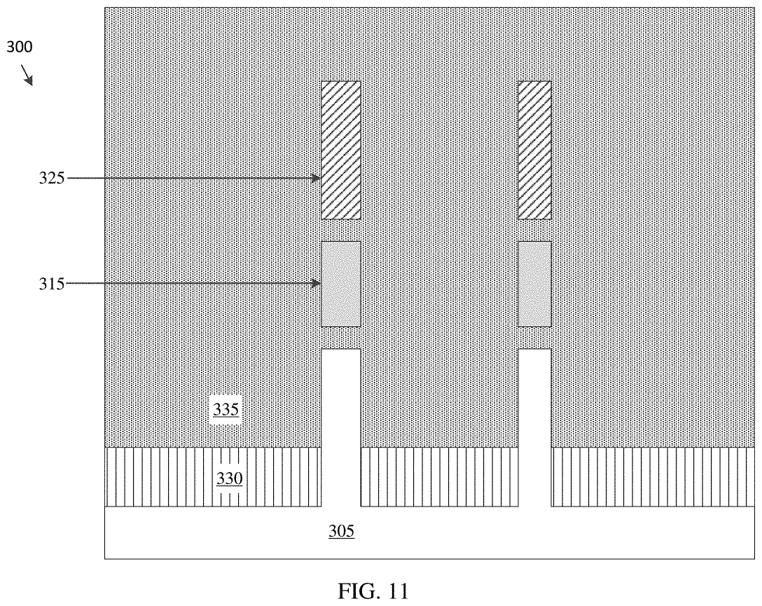

FIG. 11 illustrates a cross-section of the process stage of the formation of the device 300, in accordance with the embodiment of the present invention. A substitution process is used to form a high-k metal gate 335 on top of the shallow trench isolation layer 330. The substitution process substitutes the high-k metal gate 335 for the first sacrificial layer 310 and the second sacrificial layer 320. The high-k metal gate 335 encloses the three sides of the lower section of the column, such that, the high-k metal gate 335 is in direct contact with three sides of the substrate 305. The high-k metal gate 335 further encloses all sides of the wafer bonding layer 315 and the high-k metal gate 335 encloses all the sides the upper layer 325. Because low Ge % SiGe material 325 (Ge %<35%) is used, one can remove sacrificial SiGe materials (first sacrificial layer 310 and the second sacrificial layer 320) with high Ge % without damaging the channel material (upper layer 325). At this stage, the top PFET is with SiGe channel material and (110) surface orientation, which is favor for boosting hole mobility. The bottom NFET device is with Si channel and (100) surface orientation, which is good for electron mobility.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor device comprising:
at least one first gate all around channel having a horizontal physical orientation, wherein the at least one first gate all around channel is comprised of a first material, wherein the at least one first gate all around channel has a sidewall surface with (100) crystal orientation;
at least one second gate all around channel having a vertical physical orientation, wherein the second channel is located above the at least one first gate all around channel, wherein the at least one second gate all around channel is comprised of a second material, wherein the at least one second gate all around channel has a sidewall surface with (110) crystal orientation; and
a gate metal enclosing the at least one first gate all around channel and the at least one second gate all around channel.

2. The semiconductor device of claim 1, wherein the first material and the second material are different.

3. The semiconductor device of claim 1, wherein the first material is Si.

4. The semiconductor device of claim 3, wherein the second material is Si1-xGex, where Ge percentage x is from 5 to 35%.

5. The semiconductor device of claim 1, wherein the first material is SiGe 5 to 35$.

6. The semiconductor device of claim 5, wherein the second material is Si.

7. A semiconductor device comprising:
at least one lower channel having a vertical physical orientation, wherein the channel is taller than it is wider, wherein the at least one lower channel has a sidewall surface with (100) crystal orientation, wherein the at least one lower channel is comprised of a first material; and
at least one upper channel having a vertical physical orientation, wherein the channel is taller than it is wider, wherein the at least one upper channel has a sidewall surface with (110) crystal orientation, wherein the at least one upper channel is comprised of a second material, wherein the first material and the second material are different.

8. The semiconductor device of claim 7, wherein the first material is Si.

9. The semiconductor device of claim 8, wherein the second material is SiGe 5 to 35%.

10. The semiconductor device of claim 7, wherein the first material is SiGe 5 to 35$.

11. The semiconductor device of claim 10, wherein the second material is Si.

12. The semiconductor device of claim 7, wherein the at least one lower channel is a double gated channel.

13. The semiconductor device of claim 12, wherein the least one upper channel is a tri-gated channel.

14. The semiconductor device, of claim 13, further comprising a wafer bonding layer located between the at least one lower channel and the at least one upper channel.

15. The semiconductor device of claim 14, wherein the at least one lower channel is in direct contact with a first side of the wafer bonding layer and the at least one upper channel is in direct contact with a second side of the wafer bonding layer, wherein the first side of the wafer boding layer is different from the second side of the wafer bonding layer.

16. The semiconductor device of claim 7, wherein the at least one lower channel is a tri-gated channel.

17. The semiconductor device of claim 16, wherein the least one upper channel is a gate all around channel.

18. The semiconductor device of claim 17, further comprising a wafer bonding layer located between the at least one lower channel and the at least one upper channel.

19. The semiconductor device of claim 18, further comprising a gate metal that is in direct contact with three sides of the at least one lower channel, wherein the gate metal encloses the wafer bonding layer, and wherein the gate metal encloses the at least one upper channel.

20. A method comprising
forming a first layer sacrificial layer on a substrate;
forming a first bottom horizontal nanosheet with first semiconductor material with sidewall surface with (100) crystal orientation;
forming a second sacrificial layer on top of the first horizontal channel layer;
forming a second bottom horizontal nanosheet with first semiconductor material with sidewall surface with (100) crystal orientation;
forming a third sacrificial layer on top of the second horizontal channel layer;
forming top vertical FINs with second semiconductor material with sidewall surface with (110) crystal orientation, wherein the first semiconductor material and the second semiconductor material are different; and
etching the third channel such that the third channel has a vertical orientation.
